(19) United States
(12) Patent Application Publication
(10) Pub. No.: US 2022/0148755 A1
(43) Pub. Date: May 12, 2022

(54) FERROELECTRIC SUPERCONDUCTOR FROM BELOW TO ABOVE ROOM TEMPERATURE

(71) Applicant: UNIVERSIDADE DO PORTO, Porto (PT)

(72) Inventor: Maria Helena Braga SOUSA SOARES DE OLIVEIRA BRAGA, Porto (PT)

(21) Appl. No.: 17/601,941

(22) PCT Filed: Apr. 6, 2020
(86) PCT No.: PCT/IB2020/053276

§ 371 Date: Oct. 7, 2021

(30) Foreign Application Priority Data
Apr. 7, 2019 (PT) 115437

(51) Int. Cl. H01B 1/08; H01B 1/18; H01B 12/00

(52) U.S. Cl. CPC H01B 1/08; H01B 12/00; H01B 1/18

(57) ABSTRACT

The present invention relates to a superconductor comprising a ferroelectric with a very high dielectric constant at temperatures from below to above room temperature, in which a spontaneous dynamic alignment of the dipoles of the ferroelectric the superconductivity is induced at the surface.

The use of the innovative superconductor and application of the phenomenon with subsequent harvesting of the generated current, the ferroelectric, can be applied between two identical conductors or semiconductors, two dissimilar conductors or semiconductors, or as an insulator core of a conductor or just in contact with air.

The present invention is thus useful in applications that enable the transmission of electrical power with no losses in the fields of energy, harvest, storage, sensors, transistors, parts of a computer, photovoltaic cell or panels, wind turbines, SQUID, MRI, mass spectrometer, particle accelerators, smart grids, electric power transmission, transformers, power storage devices and/or electric motors.

### TECHNICAL FIELD

The present invention relates to a superconductor comprising a ferroelectric with a very high dielectric constant at temperatures from below to above room temperature, in which a spontaneous dynamic alignment of the dipoles of the ferroelectric the superconductivity is induced at the interface.

The use of the innovative superconductor and application of the phenomenon with subsequent harvesting of the generated current, the ferroelectric, can be applied between two identical conductors or semiconductors, two dissimilar conductors or semiconductors, or as an insulator core of a conductor or just in contact with an insulator such as air.

The present invention is thus useful in applications that enable the transmission of electrical power with no losses in the fields of energy, harvesting, storage, transistors, sensors, parts of a computer, photovoltaic cell or panels, wind turbines, SQUID, MRI, mass spectrometer, particle accelerators, smart grids, electric power transmission, transformers, power storage devices and/or electric motors.

### BACKGROUND

A Superconductor is a material capable of showing a zero resistance; it is, therefore, a property related with electrons. Superconductors are also able to maintain a current with no applied voltage, a property exploited in superconducting electromagnets such as those found in MRI machines. Experiments have demonstrated that currents in superconducting coils can persist for years without any degradation. Several materials have been reported to show superconductivity, like Be, Ti, Zr, Zn, Sn, at low temperatures (<50 K) and the high-temperature (<=135 K) cuprate superconductors, like HgBa₂Ca₂Cu₃Oₓ or the iron based FeSe. The highest temperature (150 K) superconductor is H₂S but it also requires high pressure.

A Superconductor enables, therefore, the transmission of electrical power without any loss and exhibits no heat dissipation (no Joule effect). The development of novel architectures for harvesting and subsequently storing energy brings important benefits to humankind.

A Ferroelectric material is a material that shows spontaneous electric polarization that can be reversed by the application of an external electric field. All ferroelectrics are pyroelectrics, their natural electrical polarisation is reversible.

Superconductivity can be generated at the interface between a metal and a ferroelectric material. This is due to an abrupt phase transition occurring at the metal/insulator vacuum interface (the permittivity changes abruptly for example from 10⁵ to 1), which spontaneously breaks symmetry and induces superconductivity. This is what in topological mathematics is known as a catastrophic phenomenon, as determined by the 1977 Physics Nobel Prize Philip Anderson, who also predicted that a ferroelectric material could become a superconductor at room temperature. Here it is shown, for the first time, that such a ferroelectric material with superconducting capabilities exists and it is a surface superconductor at room temperature and even above room temperature.

Superconductivity can therefore happen mostly along the interface of a metal/ferroelectric like in the devices hereafter presented configurating unconventional superconductors.

Ferroelectric-glasses with extremely high dielectric constant like Li_{3-2y}M_{y}ClO (M=Be, Ca, Mg, Sr, and Ba), Li_{3-3y}A_{y}ClO (M=B, Al), Na_{3-2y}M_{y}ClO (M=Be, Ca, Mg, Sr, and Ba), Na_{3-3y}A_{y}ClO (M=B, Al), or antiperovskites (crystalline materials) like Li_{3-2y-z}M_{y}H_{z}ClO (M=Be, Ca, Mg, Sr, and Ba), Li_{3-3y-z}A_{y}H_{z}ClO (M=B, Al), a mixture of thereof or a mixture of thereof with Li₂S, Na₂S or H₂S, or even composites involving these glass or crystalline materials mixed with polymers, as described in the present invention, can become a superconductor at the interface with a material with a substantially different dielectric constant; that material can even be air which would make the ferroelectric materials superconductors in the absence of a “device”.

### SUMMARY OF THE INVENTION

The present invention is directed to a ferroelectric-induced superconductor that can perform from below to above room temperature.

The present invention is directed to a ferroelectric-induced superconductor room temperature superconductor comprising an interface between two or more materials with very different permittivities, like a metal and a ferroelectric-material. The permittivity of a metal is considered infinite as the electric field inside the bulk metal is zero. In effect, the ferroelectric-material is more likely to be in contact with vacuum, whose relative permittivity is one, at the interface with the metal.

It is a feature of this invention to provide ferroelectricity-induced superconductivity achieved from abrupt changes of the properties of the materials in contact at the interface.

It is a feature of this invention to provide ferroelectricity-induced superconductivity that enables the transmission of electrical power with no losses during several years. The ferroelectricity-induced superconductivity does not reduce to zero the resistance of the entire device as the device is constituted by other materials and interfaces. Nevertheless, the device can perform for years, despite having some device losses.

The present invention disclose a superconductor that comprises a ferroelectric and interfaces with at least one other material, having a dielectric constant εᵣ higher than 10³ at the interface and at temperatures from −40° C. to 170° C., wherein the dipoles of the ferroelectric present a spontaneous dynamic alignment.

Furthermore, the invention reveals the superconductor in which the ferroelectric material is Li_{3-2y}M_{y}ClO (M=Be, Ca, Mg, Sr, and Ba) with 0≤y≤1, Li_{3-3y}A_{y}ClO (M=B, Al), Na_{3-2y}M_{y}ClO (M=Be, Ca, Mg, Sr, and Ba) with 0≤y≤1, Na_{3-3y}A_{y}ClO (M=B, Al) with 0≤y≤0.5, or antiperovskites (crystalline materials) Li_{3-2y-z}M_{y}H_{z}ClO (M=Be, Ca, Mg, Sr, and Ba) with 0≤y≤0.5 and 0≤z≤2, Li_{3-3y-z}A_{y}H_{z}ClO (M=B, Al) with 0≤y≤0.5 and 0≤z≤2, a mixture of thereof or a mixture of thereof with Li₂S, Na₂S, Si₂O, Li₂O, Na₂O, or H₂S or a composite mixture thereof with a polymer.

Additionally, the superconductor could presents the ferroelectric is in contact with an insulator, such as air or vacuum.

Moreover, the superconductor of the present invention has the possibility wherein the ferroelectric is in contact with two interfaces that are similar or dissimilar conductors.

The present invention also discloses a superconductor wherein the ferroelectric is the Na-based Na_{2.99}Ba_{0.005}ClO and the conductors are Cu.

The superconductor can present a configuration in that the ferroelectric is the Na-based Na_{2.99}Ba_{0.005}ClO and the conductors are Zn and Cu.

The superconductor can present a further configuration in that the ferroelectric is the Na-based Na_{2.99}Ba_{0.005}ClO and the conductors are Zn and C foam, sponge, wires, nanotubes, graphene, graphite, carbon black or any other allotrope or carbon structure with or without impurities.

The superconductor can present a further configuration in that the ferroelectric is the Li-based (1-x)Li_{2.99}Ba_{0.005}ClO+xLi_{3-2y-z}M_{y}H_{z}ClO, with 0≤x≤1, one conductor is Li and the other is a mixture of MnO₂ with carbon black and/or a binder.

The superconductor can present a further configuration in that the ferroelectric is the Na-based (1-x)Na_{2.99}Ba_{0.005}ClO+xNa_{3-2y-z}M_{y}H_{z}ClO, with 0≤x≤1, one conductor is Na and the other is a mixture of Na₃V₂(PO₄)₃ with carbon black and/or a binder.

The superconductor can present a further configuration in that the ferroelectric is in contact with two interfaces that are similar or dissimilar semiconductors or a conductor and a semiconductor.

The superconductor can present a further configuration in that the ferroelectric is the Li-based Li_{2.99}Ba_{0.005}ClO+Li₂S, the conductor is Al and the semiconductor Si.

The superconductor can present a further configuration in that the ferroelectric is the Li-based Li_{2.99}Ba_{0.005}ClO+Li_{3-2y-z}M_{y}H_{z}ClO, the conductor is Li and the semiconductor MnO₂ or a mixture of sulfur and carbon.

The superconductor can present a further configuration in that the ferroelectric is in contact with two interfaces one a semiconductor or a conductor, and the other an insulator with a conductor contact or electron collector.

The superconductor can present a further configuration in that the ferroelectric is the Na-based or Li-based and the conductors are Zn or Cu, Li, Na, a Li alloy or composite, a Na alloy or composite and the ferroelectric surface area is in contact with an insulator such as air, vacuum, polymer, plasticizer, insulating tape, glue, or binder.

The superconductor can present a further configuration in that the ferroelectric is Li-based, Li_{2.99}Ba_{0.005}ClO or a Li_{2.99}Ba_{0.005}ClO+Li_{3-2y-z}M_{y}H_{z}ClO mixture or a composite, and the conductor is Li or a Li alloy such as LiMg or a solid solution of (Li) and the ferroelectric surface area is in contact with an insulator such as air, vacuum, polymer, plasticizer, insulating tape, glue, or binder.

The superconductor can present a further configuration in that comprises a wire conductor filled with a ferroelectric.

The superconductor can present a further configuration in that comprises at least one interface between a ferroelectric and an insulator.

The superconductor can present a further configuration in that the insulator is Si₂O, a polymer, a plasticizer such as succinonitrile and/or air.

The superconductor can present a further configuration in that the insulator has an interface with two ferroelectric materials.

The superconductor can present a further configuration in that comprises at least one interface between a ferroelectric-superconductor and superconductor.

The superconductor can present a further configuration in that the ferroelectric is Li or Na-based and the superconductors are both Al or Ti or Sn, Li and Al, or Li and Ti or Sn.

The superconductor can present a further configuration in that the ferroelectric is Li or Na-based and the superconductors are HgBa₂Ca₂Cu₃Oₓ, FeSe, or H₂S.

The superconductor can present a further configuration in that the ferroelectric is a composite mixture with a polymer such as a ferroelectric-glue mixture.

The superconductor can present a further configuration in that the ferroelectric is a CaCuTiO₃, or a composite or a mixture of the ferroelectric materials as presented above.

The superconductor as described above in any one of the preceding configurations in which the dielectric constant εᵣ is higher than 10⁴, higher than 10⁵, higher than 10⁶, higher than 10⁷, higher than 10⁸ or higher than 10⁹ at the interface and at temperatures from −40° C. to 170° C., from −35° C. to 170° C., from 0° C. to 100° C., from 0° C. to 75° C. or room temperature.

The uses of the superconductor as defined presents several applications, for example: energy harvester, energy storage device, part of a sensor, part of a transistor, part of a computer, part of a photovoltaic cell or panel, part of a wind turbine, part of a SQUID, MRI, mass spectrometer, or a particle accelerator, part of a smart grid, electric power transmission, transformers, power storage devices and/or electric motors, etc.

### DESCRIPTION OF THE DRAWINGS

These and other features, aspects and advantages of the present invention will become better understood with reference to the following description and appended claims, and accompanying drawings wherein.

FIG. 1a is the embodiment of a Li-based ferroelectric with very high dielectric constant. The graph shows the relative permittivity as a function of temperature at 10 Hz.

In Which:

ε′ represents the real relative permittivity or dielectric constant

ε″ represents the imaginary relative permittivity

ε* represents the modulus of the relative permittivity

FIG. 1b is the embodiment of a Na-based ferroelectric and a conductor1=Zn/Na-based ferroelectric/conductor2=C+Cu with very high dielectric constant. The graph shows the relative permittivity as a function of temperature at (0.1 Hz for AC) and obtained by DC measurements;

FIG. 1c is the embodiment of a conductor1=Zn/Na-based ferroelectric/conductor2=C+Cu showing surface superconductivity at the surface of the ferroelectric with an abrupt decrease of the resistance of the cell between −30 and 0° C.

FIG. 2 is the embodiment of a ferroelectric-induced superconductor with conductor/ferroelectric/conductor interfaces;

FIG. 3 is another embodiment of a ferroelectric-induced superconductor with conductor/ferroelectric/semiconductor interfaces;

FIG. 4 is another embodiment of a ferroelectric-induced superconductor with conductor/ferroelectric/conductor interfaces in which most of the ferroelectric is exposed to air/insulator;

FIG. 5 is another embodiment of a ferroelectric-induced superconductor with a wire filled with the ferroelectric;

FIG. 6 is another embodiment of a ferroelectric-induced superconductor with ferroelectric/insulator/ferroelectric interfaces;

FIG. 7 is another embodiment of a ferroelectric-induced superconductor with superconductor/ferroelectric/superconductor interfaces.

### DESCRIPTION OF THE INVENTION

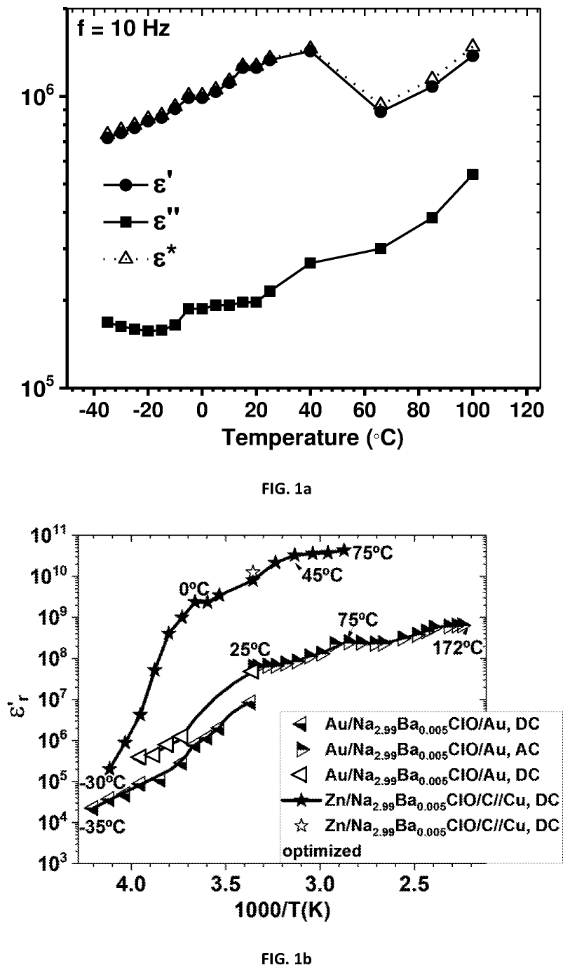

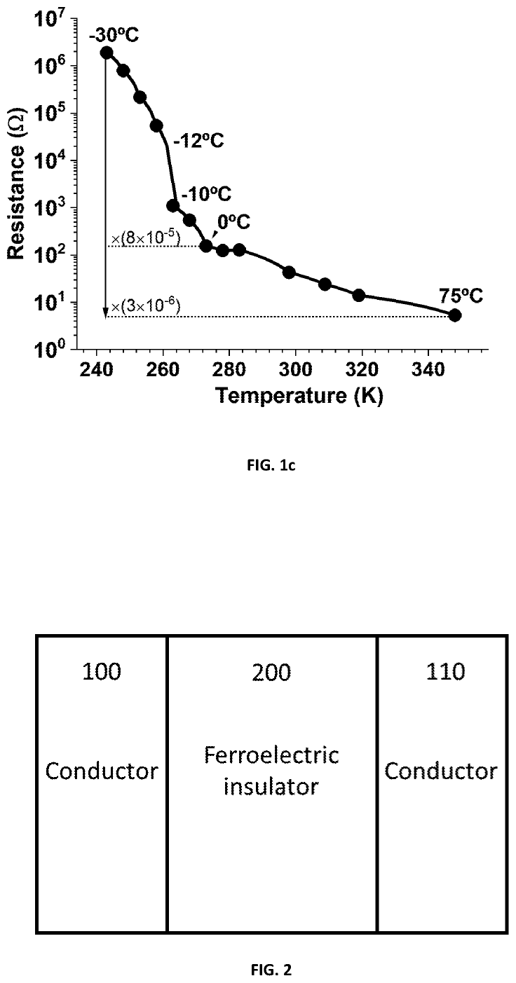

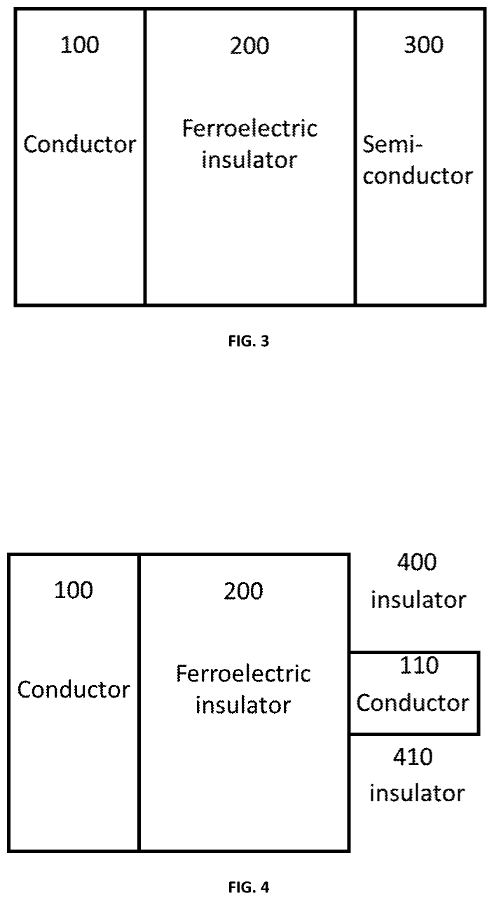

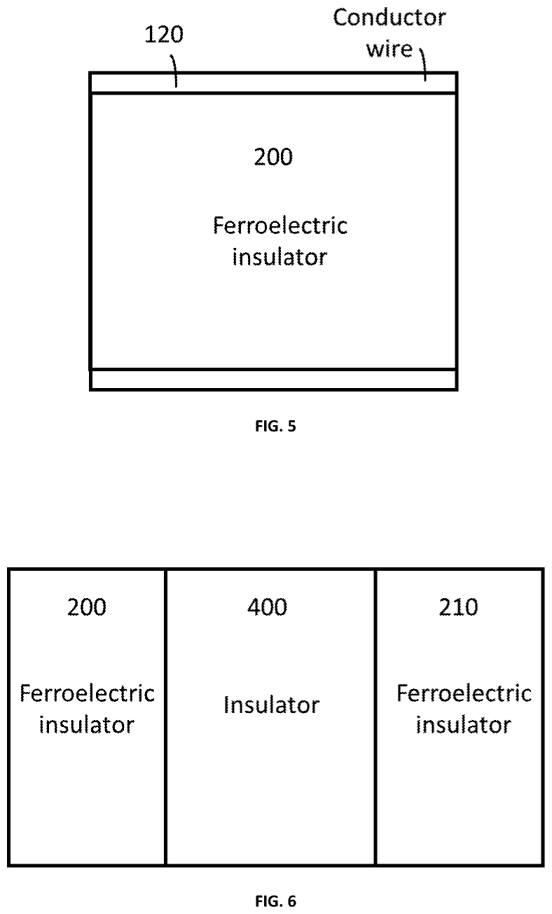

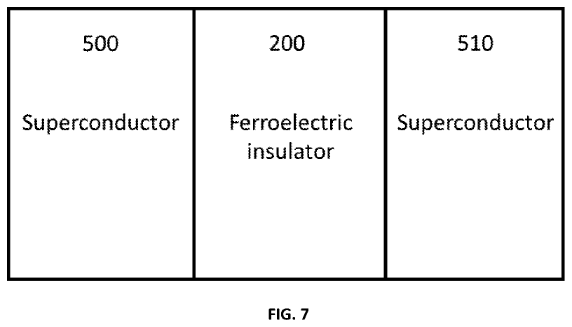

The preferred embodiments of the present invention are illustrated by way of example below and in FIGS. 1-7. As shown in FIG. 1 the ferroelectric-superconductors must have a very high dielectric constant; preferably in a range of temperatures that go from low (from 233-273 K) to room (273 to 282 K) or high temperatures (T≤500 K). As shown in FIG. 2, the ferroelectric-induced superconductor 10 includes two conductors 100 and 110, which are similar or dissimilar, and a ferroelectric material 200. As shown in FIG. 3, the ferroelectric-induced superconductor 20 includes a conductor 100, a ferroelectric material 200 and a semiconductor 300. As shown in FIG. 4, the ferroelectric-induced superconductor 30 includes two conductors 100 and 110, which are similar or dissimilar, a ferroelectric material 200 and two insulators 400 and 410 that can be similar or dissimilar. Conductor 110 is an electron collector. As shown in FIG. 5, the ferroelectric-induced superconductor 40 includes a wire conductor 120 with a ferroelectric material 200. The ferroelectric 200 can fill a shallow wire. The ferroelectric 200 can be coated by the conductor 120. As shown in FIG. 6, the ferroelectric-induced superconductor 50 includes two ferroelectric-superconductors 200 and 210 and an insulator 400. As shown in FIG. 7, the ferroelectric-induced superconductor 60 includes two superconductors 500 and 510 and a ferroelectric-insulator 200. Devices 10 to 60 allow superconductivity to be induced.

In the description of the present invention, the invention will be discussed in a laboratory environment; however, this invention can be utilized for any type of applications requiring the devices 10 to 60.

Document US 2019/0058105 A1 disclosed a piezoelectric-induced room temperature superconductor in which the device needs a pulsed current to pass through a wire with an insulator core and a metal coating and while the wire is vibrated, room temperatures superconductivity is induced. While the inventions are totally different, they are both due to non-linear phenomena and symmetry breaking. In the present invention no external current or vibration is needed or used, all the processes are spontaneous; ferroelectric alignment is spontaneous and when a high dielectric constant ferroelectric material forms a junction, for example with a metal, an abrupt phase transition occurs at the metal/insulator interface, which spontaneously breaks symmetry and induces superconductivity. Moreover, the above referred document disclosed piezoelectric material as mandatory and the present invention is based in absolutely different type of materials that are Ferroelectric.

The enablement of the ferroelectric-induced superconductivity does not relate to the ferroelectric structure, as the ferroelectric material can be an amorphous, a glass or a crystalline material, but a great deal with the dynamic coalescence and alignment of the dipoles that enables superconductivity. When the material is in this process it is far-from-equilibrium (non-equilibrium in thermodynamics).

There are three parameters which will affect superconductivity. The parameters include temperature, current density, and externally applied magnetic field strength. These parameters have one thing in common, the cooperative motion of electrons. Control of this motion via the coalescence and alignment of the dipoles constituting the ferroelectric material may lead to the achievement of room temperature superconductivity, especially if charged matter is inhomogeneous. Presently, it is believed that the mechanism of superconductivity can be induced either by bipolarons or Cooper pairing.

A bipolaron can be defined, but without limitation, as a quasiparticle consisting of two polarons.

A polaron is a fermionic quasiparticle used in condensed matter physics to understand the interactions between electrons and atoms in a solid material.

The polaron concept was firstly introduced by Landau to describe an electron moving in a dielectric crystal where the atoms move from their equilibrium positions to effectively screen the charge of an electron, known as a phonon cloud. This lowers electron mobility and increases the electron's effective mass.

A Cooper pair or BCS pair is a pair of electrons (or other fermions) bound together at low temperatures. An arbitrarily small attraction between electrons in a metal can cause a paired state of electrons to have a lower energy than the Fermi energy, which implies that the pair is bound. In conventional (BCS) superconductors, this attraction is due to the electron-phonon interactions. The important understanding is that independent of physical mechanism, the key to observed superconductivity is the strong electron-lattice (phonon) coupling. Strong electron-lattice interactions can be obtained from abrupt change in the permittivity as it can happen at the surface of an organic solar cell; thereby, providing justification for a ferroelectric-induced superconductivity enablement.

Given that the superconducting charge carriers (of mass mₛ, where μ₀ is the magnetic permeability of free space) are electrons (ē, electron charge), with a number density of superconducting charge carriers (nₛ) on the order of 10²⁰/cm³ for example in superconductors type-II, the London penetration depth λ_{L} is given by:

$${λ}_{L} = \sqrt{{m}_{s} / ( {μ}_{0} {n}_{s} {\overline{e}}^{2} )} \qquad ( equation 1 )$$

The penetration depth is determined by the superfluid density, which is a quantity that determines T_{c} in high-temperature superconductors.

The condition for the Meissner effect (perfect diamagnetism) becomes possible at room temperature. It is worth to note that:

$${n}^{* 2} = {ɛ}_{r} {μ}_{r} \qquad ( equation 2 )$$

where n*=n+ik is the complex refractive index and n is the real part of the refractive index, k the extinction coefficient, or mass attenuation coefficient, εᵣ′ is the relative real permittivity, εᵣ″ is the relative imaginary permittivity, μᵣ is the relative magnetic permeability. For non-magnetic materials μᵣ=1.

Diamagnetism is a quantum mechanical effect that occurs in all materials; when it is the only contribution to the magnetism, the material is called diamagnetic.

Some materials like water, water-based materials and Cu, C (pyrolytic and graphite), Bi, Hg, are diamagnetic, have a relative magnetic permeability that is less or equal to 1. This means that they are diamagnetic and that they are repelled by magnetic fields. Superconductors may be considered perfect diamagnets, because they expel all magnetic fields due to the Meissner effect.

The magnetic induction within a ferroelectric 200 is zero, hence dB/dt, the time rate of change of B is zero as well (the two conditions for deriving the London equation describing the superconducting state, from the Maxwell equations). From Faraday's law we obtain that the curl of the electric field under (dB/dt=0) condition is zero. Combining this result with the form of Ohm's law relating electric field strength with the product of current density and electrical resistivity (time independent), it can be shown that the electric field must be zero (since we have current) only under the condition of zero electrical resistivity, hence ideal electrical conductivity. Thus, the present invention meets the second requirement for super-conductivity mentioned above.

The third requirement for superconductivity, namely the enablement of macroscopic quantum coherence is best described by the conventional BCS (Bardeen, Cooper, and Schrieffer) theory. As the current flows, for example, along the conductor 100, positive ions or dipoles aligned at the interface of the ferroelectric 200 will create an attractive force between electrons (of opposite spins and opposite momentum), which normally repel one another, due to Coulombic repulsion. Thus, electron pairs, named Cooper pairs, will be formed, which will subsequently condense into a single quantum mechanical state, represented by a unique wave function. This is equivalent with macroscopic quantum coherence and can be further exemplified by the creation of the ‘supercurrent’ in the ‘gap’ material of a Josephson junction like 50 or 60. In the present invention, under room or higher temperature conditions, the thermal agitations (fluctuations)-induced lattice vibrations will couple with the coalescent dipoles, dipoles or ions vibrations allowing the dipoles to align even further, reducing the internal resistance to the movement of ions and/or dipoles and increasing the dielectric constant to generate a virtual ‘soup’ of fluctuations, a highly non-linear, far-from-equilibrium environment at the interface of the conductor 100 and ferroelectric 200.

The complex interactions between a physical system and its surroundings (environment), disrupt the quantum mechanical nature of a system and render it classical under ordinary observation. This process is known as decoherence. However, it is argued that we can retard (delay) decoherence (and possibly even suppress it-namely decouple a physical system from the environment) by accelerated spin and/or accelerated vibration of electrically charged matter under rapid acceleration transients. This may be the very condition to achieve a state of macroscopic quantum coherence, the idea being that we never let the system achieve thermodynamic equilibrium, by constantly delaying the onset of relaxation to equilibrium (hence the production of maximal entropy is delayed). The system may “violently” react by generating “anomalous” emergent phenomena, such as room temperature superconductivity. If for example one of the preferred embodiments like 10, is connected to an LED, or a diode, the thermodynamic equilibrium is retarded since a small current is continuously circulating in the external circuit. At −20° C., the vibration of electrically charged matter is observed in a ferroelectric-induced superconductor 10, 20, or 30; and at room temperature, a supercurrent can be induced for at least three years in a ferroelectric-induced superconductor 10, 20, or 30.

The Prigogine effect (Ilya Prigogine, Nobel Prize of Chemistry 1977) as discussed in the paper “The high energy electromagnetic field generator” published in Int. J. Space Science and Engineering, Vol. 3, No. 4, 2015, pp. 312-317, explains that under three conditions, a chaotic system (the aforementioned ‘soup’ of fluctuations) can self-organize into an orderly state, equivalent to the state of macroscopic quantum coherence. These conditions are the existence of a highly non-linear medium (as in this case a ferroelectric material), an abrupt departure far-from-thermodynamic equilibrium, and an energy flux (caused by spontaneous alignment of the dipoles and ionic conduction due to the need to align the Fermi levels of conductors 100 and/or 110 with the ferroelectric 200 at open circuit or by closing the external circuit) to maintain the process of self-organization (order from chaos). This shows that the present invention has macroscopic quantum coherence, fulfilling the final requirement for superconductivity. As shown above, all three conditions for superconductivity are met by the present invention, thus, as a result, low to higher temperature superconductivity is herein established and enabled.

It is possible that the key to superconductivity is the enablement of local macroscopic quantum coherence, namely the ability of a macroscopic object to act as if quantum mechanical in nature exhibiting such phenomena as superposition, entanglement, tunnelling. In summary, one can argue that the synthesis of three physical mechanisms, namely the Meissner effect, the Cooper effect (or bipolaron formation), and the Prigogine effect leads directly to the possibility of room to high temperature superconductivity, at least in the preferred embodiments. Therefore, the supercurrent may be generated along the interface (boundary) between the conductor 100, semiconductor 300, insulator 400, superconductor 500 and a ferroelectric 200.

The ferroelectric-induced superconductor can show negative capacitance phenomena at the interface of a conductor 100 and a ferroelectric 200 in a superconductor 10, 20, or 30, when the Fermi level of the conductor 100 is higher than the Fermi level of the ferroelectric 200, leading to the formation of an Electrical Double Layer Capacitor (EDLC) to align the Fermi levels (formed by the conductor's electrons and the ferroelectric cations or positive dipole-ends) and an inverted Electrical Double Layer Capacitor (EDL-C′) in series with the EDLC at the interface; the inverted capacitor can be formed by the ferroelectric cations and the negative polarons or Cooper pairs which will be repelled back to the surface by the negative-ends of the dipoles or circulate in the second layer by the action of the cations aligned at the EDLC and the positive ends of the dipoles on the opposed layer.

1. A superconductor comprising:
a ferroelectric and interfaces with at least one other material,
having a dielectric constant εᵣ higher than 10³ at the interface
and at temperatures from −40° C. to 170° C.,
wherein the dipoles of the ferroelectric present a spontaneous dynamic alignment.

2. The superconductor of claim 1 in which the ferroelectric material is Li_{3-2y}M_{y}ClO (M=Be, Ca, Mg, Sr, and Ba) with 0≤y≤1, Li_{3-3y}A_{y}ClO (M=B, Al), Na_{3-2y}M_{y}ClO (M=Be, Ca, Mg, Sr, and Ba) with 0≤y≤1, Na_{3-3y}A_{y}ClO (M=B, Al) with 0≤y≤0.5, or antiperovskites (crystalline materials) Li_{3-2y-z}M_{y}H_{z}ClO (M=Be, Ca, Mg, Sr, and Ba) with 0≤y≤0.5 and 0≤z≤2, Li_{3-3y-z}A_{y}H_{z}ClO (M=B, Al) with 0≤y≤0.5 and 0≤z≤2, a mixture of thereof or a mixture of thereof with Li₂S, Na₂S, Si₂O, Li₂O, Na₂O, or H₂S or a composite mixture thereof with a polymer.

3. The superconductor of claim 1 or claim 2 wherein the ferroelectric is in contact with an insulator, such as air or vacuum.

4. The superconductor of any one of the preceding claims wherein the ferroelectric is in contact with two interfaces that are similar or dissimilar conductors.

5. The superconductor of any one of the preceding claims wherein the ferroelectric is the Na-based Na_{2.99}Ba_{0.005}ClO and the conductors are Cu.

6. The superconductor of any one of the preceding claims wherein the ferroelectric is the Na-based Na_{2.99}Ba_{0.005}ClO and the conductors are Zn and Cu.

7. The superconductor of any one of the preceding claims wherein the ferroelectric is the Na-based Na_{2.99}Ba_{0.005}ClO and the conductors are Zn and C foam, sponge, wires, nanotubes, graphene, graphite, carbon black or any other allotrope or carbon structure with or without impurities.

8. The superconductor of any one of the preceding claims wherein the ferroelectric is the Li-based (1-x)Li_{2.99}Ba_{0.005}ClO+xLi_{3-2y-z}M_{y}H_{z}ClO, with 0≤x≤1, one conductor is Li and the other is a mixture of MnO₂ with carbon black and/or a binder.

9. The superconductor of any one of the preceding claims wherein the ferroelectric is the Na-based (1-x)Na_{2.99}Ba_{0.005}ClO+xNa_{3-2y-z}M_{y}H_{z}ClO, with 0≤x≤1, one conductor is Na and the other is a mixture of Na₃V₂(PO₄)₃ with carbon black and/or a binder.

10. The superconductor of any one of the preceding claims wherein the ferroelectric is in contact with two interfaces that are similar or dissimilar semiconductors or a conductor and a semiconductor.

11. The superconductor of any one of the preceding claims wherein the ferroelectric is the Li-based Li_{2.99}Ba_{0.005}ClO+Li₂S, the conductor is Al and the semiconductor Si.

12. The superconductor of any one of the preceding claims wherein the ferroelectric is the Li-based Li_{2.99}Ba_{0.005}ClO+Li_{3-2y-z}M_{y}H_{z}ClO, the conductor is Li and the semiconductor MnO₂ or a mixture of sulfur and carbon.

13. The superconductor of any one of the preceding claims wherein the ferroelectric is in contact with two interfaces one a semiconductor or a conductor, and the other an insulator with a conductor contact or electron collector.

14. The superconductor of any one of the preceding claims wherein the ferroelectric is the Na-based or Li-based and the conductors are Zn or Cu, Li, Na, a Li alloy or composite, a Na alloy or composite and the ferroelectric surface area is in contact with an insulator such as air, vacuum, polymer, plasticizer, insulating tape, glue, or binder.

15. The superconductor of any one of the preceding claims wherein the ferroelectric is Li-based, Li_{2.99}Ba_{0.005}ClO or a Li_{2.99}Ba_{0.005}ClO+Li_{3-2y-z}M_{y}H_{z}ClO mixture or a composite, and the conductor is Li or a Li alloy such as LiMg or a solid solution of (Li) and the ferroelectric surface area is in contact with an insulator such as air, vacuum, polymer, plasticizer, insulating tape, glue, or binder.

16. The superconductor of any one of the preceding claims that comprises a wire conductor filled with a ferroelectric.

17. The superconductor of any one of the preceding claims that comprises at least one interface between a ferroelectric and an insulator.

18. The superconductor of any one of the preceding claims in which the insulator is Si₂O, a polymer, a plasticizer such as succinonitrile and/or air.

19. The superconductor of any one of the preceding claims in which the insulator has an interface with two ferroelectric materials.

20. The superconductor of any one of the preceding claims that comprises at least one interface between a ferroelectric-superconductor and superconductor.

21. The superconductor of any one of the preceding claims in which the ferroelectric is Li or Na-based and the superconductors are both Al or Ti or Sn, Li and Al, or Li and Ti or Sn.

22. The superconductor of any one of the preceding claims in which the ferroelectric is Li or Na-based and the superconductors are HgBa₂Ca₂Cu₃Oₓ, FeSe, or H₂S.

23. The superconductor of any one of the preceding claims in which the ferroelectric is a composite mixture with a polymer such as a ferroelectric-glue mixture.

24. The superconductor of any one of the preceding claims in which the ferroelectric is a CaCuTiO₃, or a composite or a mixture of the ferroelectric materials presented in claim 2.

25. The superconductor of any one of the preceding claims in which the dielectric constant εᵣ is higher than 10⁴, higher than 10⁵, higher than 10⁶, higher than 10⁷, higher than 10⁸ or higher than 10⁹ at the interface and at temperatures from −40° C. to 170° C., from −35° C. to 170° C., from 0° C. to 100° C., from 0° C. to 75° C. or room temperature.

26. Use of the superconductor as defined according to any one of the preceding claims as an energy harvester, energy storage device, part of a sensor, part of a transistor, part of a computer, part of a photovoltaic cell or panel, part of a wind turbine, part of a SQUID, MRI, mass spectrometer, or a particle accelerator, part of a smart grid, electric power transmission, transformers, power storage devices and/or electric motors.
